(19) United States
(12) Patent Application Publication
(10) Pub. No.: US 2005/0274480 A1
(43) Pub. Date: Dec. 15, 2005

(54) Reduction of spontaneous metal whisker formation

(76) Inventors: Michel W. Barsoum, Moorestown, NJ (US); Elizabeth Nola Hoffman, Aldan, PA (US); Roger Davidge Doherty, Wynnewood, PA (US)

Correspondence Address: KNOBLE YOSHIDA & DUNLEAVY, LLC;Suite 1350, Eight Penn Center, 1628 John F. Kennedy Blvd., Philadelphia, PA, 19103, US

(21) Appl. No.: 11/136,117

(22) Filed: May 24, 2005

Related U.S. Application Data
(60) Provisional application No. 60/573,931, filed on May 24, 2004.

(51) Int. Cl. B22D 19/14; B22D 19/16; B22D 23/00; H01L 21/31; H01L 21/469

(52) U.S. Cl. 164/97; 438/780

(57) ABSTRACT

The spontaneous growth of low melting point metal whiskers poses a serious reliability problem in the semiconductor industry. With the introduction of lead-free technology, this problem has become more acute and a solution is urgently needed. To date this 50+ year old problem has resisted interpretation and no solution exists. The likely driving force for spontaneous growth of low melting point metal whiskers is the volume expansion associated with the dissolution and/or reaction of oxygen and/or nitrogen in the metal. The volume expansion creates a local compressive stress that pushes the whisker up exposing fresh metal. The repetition of this process—a form of chemical ratcheting—results in the linear growth of the whiskers. The present invention provides compositions and methods for the reduction and/or prevention of diffusion of oxygen and/or nitrogen into the low melting point metal to reduce or prevent metal whisker formation.

### CROSS-REFERENCE TO RELATED APPLICATIONS

This application claims the benefit of U.S. provisional patent application No. 60/573,931, filed on May 24, 2004, under the provisions of 35 U.S.C. § 119(e).

### BACKGROUND OF THE INVENTION

1. Field of the Invention

The present invention relates to compositions and methods for the reduction and/or prevention of metal whisker formation in low melting point metals.

2. Brief Description of the Prior Art

The spontaneous room temperature growth of low melting point metal whiskers of materials such as Sn, Cd, Bi and Zn [1-6], and even from Al surfaces at elevated temperatures [7-9], is a well-established phenomenon that has resisted interpretation for over 50 years. Metal whiskers create significant problems in the semiconductor field because they are conductive and will cause electrical shorts if they manage to bridge tightly-spaced electrical conductors. Electrical shorts may lead to computer circuit failures which in turn can lead to catastrophic equipment loss such as complete or partial satellite failure, airplane and military hardware failure, failure of medical equipment such as pace makers and apnea monitors, power relay failures and the failure of computer components found in networks and servers and the like. (See http://nepp.nasa.gov/whisker/)

With the world-wide reduction in the use of potentially hazardous materials such as lead (Pb), electronics manufacturers are eliminating lead from most of their products, such as, for example, solder. Pure Sn and Zn plating, particularly when electroplated, is one of the leading causes of whisker formation. Additionally the miniaturization of electronic circuits highlights the increased awareness of whisker formation.

The mechanisms by which metal whiskers grow have been studied for many years. A single accepted explanation of the mechanisms has not been established. Some suggest that metal whiskers may grow to relieve stress (especially “compressive” stress) within the tin plating. Others contend that growth may be attributable to recrystallization and abnormal grain growth processes affecting the tin grain structure (which may or may not be affected by residual stress in the tin plated film).

In the case of stress within the tin plating, there are some commonly accepted factors that can impart additional residual stress. For example, residual stresses within the tin plating may be caused by factors such as the plating chemistry and process. Electroplated finishes (especially “bright” finishes) appear to be most susceptible to whisker formation reportedly because bright tin-plating processes can introduce greater residual stresses than other plating processes. The change in lattice spacing may impart stresses to the tin plating that may be relieved through the formation of tin whiskers. Externally applied compressive stresses such as those introduced by application of torque to a nut or a screw may contribute to whisker formation. Bending or stretching of the surface after plating, such as during lead-formation prior to mounting of an electronic component may contribute to whisker formation. Scratches or nicks in the plating and/or the substrate material introduced by handling, probing, etc, and coefficient of thermal expansion mismatches between the plating material and substrate may also lead to whisker formation.

Shapes: Whiskers may be straight, kinked, hooked or forked. Their outer surfaces are often grooved. Some growths may form as nodules or pyramidal structures that are hereafter referred to as hillocks.

1. Incubation (Dormancy) Period: Experimenters report the incubation period may range from days to years. This attribute of whisker growth is particularly problematic because meaningful experiments to determine the propensity for a particular process to form whiskers may need to span very long periods of time.

2. Growth Rate: Growth rates from 0.03 to 0.9 mm/yr have been reported. Growth is highly variable and is likely to be determined by a complex relationship of factors including plating chemistry, plating thickness, substrate materials, grain structure and environmental storage conditions.

3. Whisker Length: Whiskers as long as a few millimeters are not uncommon with some experimenters observing whiskers as long as 10 mm (400 mils) in length.

4. Whisker Diameter: Typical diameters are a few microns with some reports as large as 50 um

5. Environmental Factors: There is a great deal of contradictory information regarding environmental factors that might affect whisker formation. Several organizations are attempting to devise accelerated test methods to determine a particular plating process's propensity to form tin whiskers. However, to date, there are no accepted test methods for evaluating whisker propensity. Indeed, much of the experimental data compiled to date has produced somewhat contradictory findings regarding which factors accelerate, or retard, whisker growth.

Temperature: Some experimenters report that ambient temperatures of approximately 50° C. are optimal for whisker formation, while others observe that whiskers grow faster at room temperatures (22° C. to 25° C.). Reportedly, whisker growth ceases at temperatures above 150° C. when Sn is involved

Pressure: Whiskers will grow in vacuum as well as earth based atmospheric pressure.

Moisture: Some observe that whiskers form more readily in high humidity (85% RH) whereas others report that moisture is not a contributing factor

Thermal Cycling: Some experimenters report that thermal cycling increases the growth rate of whiskers, but others report no effect due to thermal cycling.

Over the years many models and mechanisms have been proposed; some were based on surface energy effects [10,11] stored energy [12], internal stresses [3-4], re-crystallization [1], and the formation of inter-metallics [6], among others [2]. With the exception of the surface energy models [10,11]—both of which assume negative whisker surface energies—all other models agree that compressive stresses are responsible for the growth of the whiskers. What has remained unclear to date is the origin of these compressive stresses and how they result in whisker growth. Recently a series of publications [13-18] have dealt with the growth of Sn whiskers from tin plated on copper lead frames. In this model the origin of the macrostress is assumed to be the formation of the intermetallic Cu₆Sn₅. While this argument may, on first impression, seem plausible, upon further inspection this model has some serious deficiencies. First, the volume change for the reaction
6 Cu+5 Sn=Cu₆Sn₅
is actually 5% negative. In a recent review article, to account for the growth of 0.3 mm Sn whiskers in a year (equivalent to a rate of ≈0.1 Å/s), Zheng and Tu [18] had to assume a room temperature grain boundary diffusion coefficient, D, of Cu in Sn of the order of 10⁻⁸ cm²/s. This D value is not only orders of magnitude higher than reported previously [6], but more importantly, if one assumes such a D, the characteristic diffusion distance—√Dt—in a year would be on the order of 5 mm. Such a distance is at least two orders of magnitude thicker than most Sn thin films studied. The diffusion based-model also fails to account for the linear growth rates of the whiskers [1,2]. Tin whiskers have also been observed in many systems in which intermetallic formation is impossible [1,2].

Furthermore, in some of the early reports, whisker activity was found to be a function of atmosphere [19,20]; a fact that cannot be reconciled with any of the current models proposed.

By now it is fairly well established that the ternary carbides and nitrides—with Mₙ₊₁AXₙ chemistry, where n is 1, 2, or 3, M is an early transition metal, A is an A-group element, and X is carbon and/or nitrogen—represent a new class of solids with unusual and sometimes unique properties [21,22]. These so-called MAX-phases exhibit properties generally associated with both ceramics and metals; relatively lightweight and oxidation resistant, yet readily machinable and resistant to thermal shock [21,22]. Of special interest to this work is the ternary carbide Zr₂InC. This phase was first synthesized in powder form in 1967 by Jeitschko and Nowotny [23], and as far as we are aware, has never been synthesized in bulk or thin film form.

In 1999 gallium (“Ga”) whiskers were observed to self-extrude from Cr₂GaN bulk samples [24,25]. Initially, it was postulated that the basal planes of Cr₂GaN were the Ga source [24]. Shortly, thereafter it was discovered that the actual source of the Ga was excess, or unreacted, Ga present at the grain boundaries [25]. In the same letter, it was postulated the driving force for this new phenomenon was a surface energy driven dewetting [25]. Working on the Ga system was complicated by its low melting point. Recently, indium (“In”) structures, reminiscent of the Ga ones, were observed sprouting from predominantly single-phase samples of Zr₂InC.

Interestingly, sixty years ago it was reported that a ≈1.5 mm coating of resin suppressed Zn and Cd whisker growth [26].

Plating process technology has advanced to the point that major plating developers claim whisker resistant plating. This is accomplished partly by controlling residual stress in the plated Sn film through the use of optimized plating parameters (current density, grain growth, and content of impurities, especially carbon, hydrogen and zinc, etc.). However, no high-Sn plating process can truly be whisker free. Matte Sn is one viable option and other options including mixtures such as tin/bismuth, tin/silver/copper, tin/silver/tin/silver/bismuth and tin/copper have been developed but each of these alternatives have drawbacks such as toxicity, higher melting points, low availability coupled with high cost and more complex and difficult process controls.

In view of the foregoing, there remains a need in the art for methods for the reduction and/or prevention of low melting point metal whisker formation, which are cost-effective.

### SUMMARY OF THE INVENTION

One aspect of the present invention relates to compositions for the reduction and/or prevention of metal whisker formation in metals such as Sn, In, Ga, Cd, Bi, Zn and Al. The compositions include a metal, which has a tendency toward whisker formation and an oxygen and/or nitrogen barrier to at least reduce the amount of oxygen and/or nitrogen that contacts the metal.

The present invention also relates to methods for the reduction and/or prevention of metal whisker formation. In the method, an oxygen and/or nitrogen barrier is provided to at least reduce the amount of oxygen and/or nitrogen that contacts the metal, to thereby slow, reduce and/or prevent metal whisker formation.

In another aspect, the present invention relates to a method for the prevention of whiskers by growing the grains of the metal film that is prone to whisker formation to as large a size as possible. By so doing the compressive stresses are reduced and whisker formation is reduced or prevented.

### BRIEF DESCRIPTION OF THE DRAWINGS

FIGS. 1a-1d include representations of SEM micrographs of:
a) A fractured Zr₂InC surface covered with a thin film of In, as determined by EDS. The presence of In at the grain boundaries is obvious.
b) A whisker growing from the center of an In island present at a triple point.
c) Whisker growth at the In/Zr₂InC interface, wherein the cross-sectional shape and size of the In whisker is determined by the grain boundary geometry.
d) Extrusion of an In “wall” growing out of a crack.
   In both of FIGS. 1b and 1c, note striations parallel to the whisker axis. In FIGS. 1c and 1d, note nearly equally spaced striations parallel to the sample surface.

FIG. 2 is a representation of whisker activity after 3 months of two halves of the same sample, in which one half was held in:
(a) air, and
(b) a vacuum.

FIG. 3 is a schematic of the process as envisioned herein. Oxygen (or nitrogen) diffuses down the grain boundaries, and results in compressive stresses. The compressive stresses in turn result in the formation of the whiskers.

### DETAILED DESCRIPTION OF THE PREFERRED EMBODIMENTS

In one aspect, the present invention relates to a method for the provision of thin films of Zr₂InC. The Zr₂InC samples were synthesized by ball milling powders of Zr (−325 mesh, ProChem 99.9%), In (−325 mesh, Alpha Aesar 99.99%) and graphite (−300 mesh, Alpha Aesar 99%). The mixed powders were vacuum-sealed in borosilicate glass tubes, which in turn were collapsed by heating to 500° C. for 2 hours, followed by heating to 600° C. for 9 h. The collapsed tubes were placed in a hot isostatic press (hereinafter “HIP”), which was heated to 750° C.; and held at temperature for ≈1.5 hour, while the Ar gas pressure was increased to ≈70 MPa. Once pressurized, the temperature was further increased to 1300° C. and held for 12 hours. The pressure at temperature was ≈90 MPa.

X-ray diffraction (hereinafter “XRD”), scanning electron microscopy, SEM, and energy dispersive spectroscope (hereinafter “EDS”), analyses confirmed that the HIP'ed samples were fully dense and predominantly single phase with unreacted In at the grain boundaries (FIG. 1a). Differential scanning calorimetery (hereinafter “DSC”), analysis indicated the In content was ≈4 vol. %. The majority of grains ranged in size between 3-5 μm (FIG. 1a).

In general, the method for the provision of thin films of Zr₂InC involves the steps of mixing powders of Zr, In and carbon, placing the mixture in a vacuum-sealed environment, and subjecting the mixture of powders to high temperature and pressure to form a thin film. Suitable temperatures are about 700° C. to about 1400° C., and suitable pressures are about 50-150 MPa.

After a period of several weeks at room temperature, In whiskers appeared to exude from the grain boundaries of the Zr₂InC (FIGS. 1b and c). The striations parallel to the whisker axes (FIGS. 1b and c) strongly suggest they were extruded and are reminiscent of other metal whiskers observed over the years. The size and shape of the whisker cross-section depended on the shape of the grain boundary from which it was extruding (FIG. 1c). Additionally, roughly equally spaced striations perpendicular to the whisker axis are observed in FIGS. 1c and 1d). In a few instances, a network of cracks developed during mounting of the samples. With time, these cracks filled with In resulting in the formation of microscopic In walls. In other words, the In was found to extrude uniformly out of these cracks (FIG. 1d).

To accelerate whisker growth, some samples were heated in situ in a scanning electron microscope chamber. The samples were observed in real time during heating, soaking at a set temperature below the melting temperature of In (157° C.). The whiskers (not shown) grew from their base at a rate that was constant with time. In agreement with previous work [1], there was also no correlation between whisker diameters and their growth rates.

### EXAMPLE 1

To determine the effect of atmosphere on whisker growth, a sample was sectioned in two; each half was cold mounted and polished down to 60 nm silica. One sample was sealed in an evacuated borosilicate glass tube; the other was exposed to the atmosphere. After three months, the glass tube was broken and the surface of the sample held in air (FIG. 2a) was compared to the surface of a sample held in the evacuated tube (FIG. 2b). From these figures it is clear the sample held in air had significantly more whisker activity than the sample held in the evacuated tube. The whiskers found on the sample exposed to ambient atmosphere were also significantly longer than the hillocks that formed on the evacuated sample (compare FIGS. 2a and 2b).

The results shown in FIG. 2 are important because they tend to show that the driving force for whisker formation is a reaction between either oxygen and/or nitrogen in the atmosphere, and unreacted In.

### EXAMPLE 2

A 50 wt. % Al—Sn alloy was melted and chill cast by pouring into a metal dish. After polishing, one sample was sealed in an evacuated glass tube, and another was held in air after a portion of its surface was coated with nail polish. Two weeks later, the polymer coating was dissolved in acetone and all three surfaces, the uncoated surface held in a vacuum, the uncoated surface held in air and the coated surface held in air, were examined. In all cases, small Sn hillocks were observed. The density of the Sn hillocks was higher in the surface exposed to air and whiskers appeared exclusively on surfaces exposed to air.

These results show that the driving force for whisker growth is a component of air, namely, oxygen or nitrogen. This driving force manifests itself as a reaction between oxygen or nitrogen and the metal. Since no nitrogen was found in the whiskers of the present example, and oxygen is more reactive than nitrogen, it was concluded that the whiskers formed in this specific example as a result of an oxidation reaction.

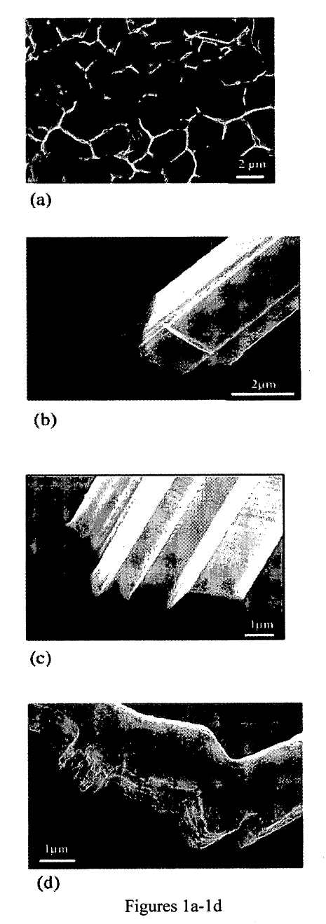

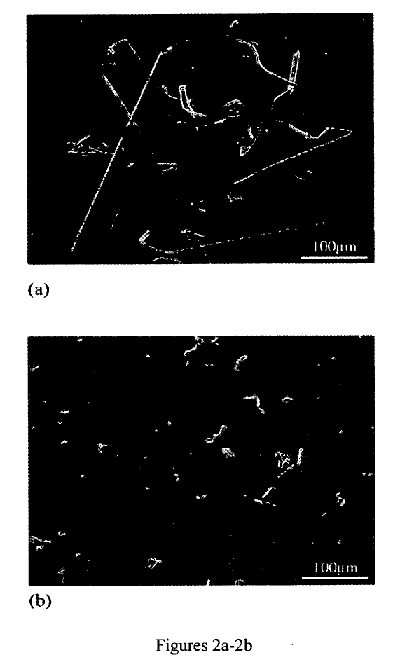

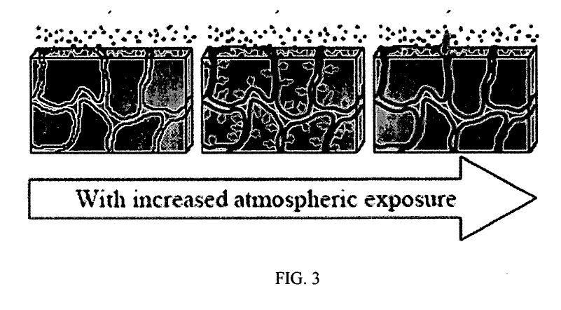

The model depicted schematically in FIG. 3 is one possible explanation of the results. In this model, oxygen and/or nitrogen diffuse down the interface between the SM and the substrate. The volume increase results in compressive stresses that ultimately are responsible for growth of the whiskers. Note that in this model the oxygen is diffusing down all SM/substrate interfaces and whisker growth only occurs in select areas.

In some cases, the whiskers did not grow at the In/Zr₂InC interface (FIG. 1b); an observation that rules out surface energy as a driving force. Note also that had surface energy been the driving force, a correlation would have been found between the whisker diameters and their rate of growth. Such a correlation has not been observed in this or earlier work.

This model requires the presence of oxygen and/or nitrogen for whiskers to form and it was thus somewhat surprising to detect some growth in evacuated environments such as the SEM and the glass tube. This growth can be attributed to either the presence of trace amounts of oxygen and/or nitrogen in the atmosphere and/or to oxygen and/or nitrogen adsorbed unto the surface. It is not unreasonable to assume that such adsorbed gases could surface diffuse to the active In sites temporarily fueling whisker growth. Such a scenario would explain the formation of the hillocks that formed in the glass tube (FIG. 2b). It would also explain the results of Chang and Vook et al. [7] who have shown that when Al thin films were deposited and/or annealed in ultra high vacuum, UHV, no hillock formation was noted. When similar films were deposited in high vacuum—where the oxygen and/or nitrogen activity in the gas phase was higher—and/or annealed in high vacuum or exposed to air and then annealed in UHV, hillocks formed. In other words, hillock growth was correlated to exposure to air and/or residual oxygen and/or nitrogen in the gas phase.

The present model is consistent with the fact that atmospheric oxygen and/or nitrogen and the presence of water vapor accelerate whisker growth [20]. Similarly, Baker and Koehlere [19] held Cd thin films in vacuum for up to 34 days, with no sign of whisker formation. However, when the same films were removed and held in air, in three days short whiskers, 5 to 10 μm, long appeared.

One of the mysteries of spontaneous growth of metal whiskers is their nucleation; i.e. why the whiskers grow at certain locations and not others (FIG. 2). One possibility is that the whiskers grow only in areas where the native oxide layer is weak or thin. (Native oxide layers are present on most metals) If the native oxide is too thick, the oxygen diffusional flux through it could be insufficient to cause whisker growth. Consistent with this notion are two observations. First, heating our samples in air to modest temperatures destroyed their ability to exude In. The same was observed for Sn; at 200° C., the growth of whiskers stops, presumably as a result of heavy oxidation [20]. Second, freshly fractured surfaces appear to be more active than polished surfaces. A good example is the filling of cracks formed during mounting of the sample with In (FIG. 1d). In general most thin cracks get filled with In, in contradistinction, only very select areas on the surface exude In. It is important to note here that the filling of these cracks is believed to be a two-step process. First, the grain boundaries exposed to the fresh surfaces exude In into the crack and fill it up. Once filled the process continues by the mechanism proposed in FIG. 3.

Whisker growth is apparently a thin film phenomenon. Without being bound by theory, it appears that the presence of the metal in thin film form, somehow allows for the build-up of the requisite pressure. This may be related to the grain size of the metal.

It is important to note that that the reaction with the oxygen and/or nitrogen in the atmosphere may not be the only reason for the growth of metallic whiskers. It is well established that external compressive stresses can enhance the growth rates of whiskers by factors as high as 10,000 [3-5]. Kim et al. [9] have elegantly shown that hillocks formed in Al films sputtered on Si substrates are created when the thermal stresses were of the order of 400 MPa. The hillocks formed to relieve the compressive stresses, and once relieved, no further growth of the hillocks was noted. It is important to note that these samples were annealed in a 5% H₂, balance N₂ gas mixture where presumably the oxygen partial pressure was exceedingly low, and thus oxygen diffusion would not have occurred.

Based on this model, there are two possible solutions to the problem. The first is to keep the oxygen and/or nitrogen from diffusing into the soft metal. To exemplify this, a 50-50 wt. % Al—Sn composition was melted in air and quenched. The resulting microstructure was one where the Sn was located at the grain boundaries of the Al grains. As before, part of the sample was placed in an evacuated glass tube, another part of the sample was left in air, and a third part of the sample was coated with a diffusion barrier, in this case, nail polish, and stored in air. After a week the whisker activity was most intense at the triple points of the surface that was uncoated, followed by the coated samples, indirectly confirming the results discussed above.

Based on the morphology of the whiskers grown and the fact that whisker growth is promoted by exposure to the atmosphere, this model for whisker growth suggests that the driving force is a volume change upon reaction with atmospheric oxygen. This model not only explains the present results, but also many of the results that had been reported in the literature and had resisted interpretation for decades. Based on this model, the solution to the problem is to coat whisker prone surfaces with an oxygen and/or nitrogen diffusion barrier.

Some suitable barrier layers include conventional coatings that are employed to reduce or prevent air permeation to a surface. Typical materials for providing this type of barrier are paints and sealants. Frequently, such paints and sealants are based on polymeric coating materials. Examples of such sealants are polyvinyl chloride resins and polyanilines. Another example of such a sealant are polyolefin resins such as vinyl acetate polymers or copolymers with other monomers. Preferably, water-based polymers for this purpose have a viscosity in excess of 1000 mPa/s and a solid content of about 20-40% by weight. One example of suitable water-based resins can be found in U.S. Pat. No. 6,417,252, (Hiraoka, et al.), the disclosure of which is hereby incorporated by reference. Another example of a suitable material is nail polish.

It is also possible to employ semi-conductive polymeric coatings to reduce metal whisker formation. An example of this is described in U.S. Pat. No. 6,562,201, (Dowling), the disclosure of which is hereby incorporated by reference. Such coatings can be provided by, for example, spraying, dipping, or painting.

Yet another type of coating that may be employed is an amorphous substance, such as zirconium phosphate or chromium chromate, to coat the low melting metal. An example of this is shown in U.S. Pat. No. 6,672,917, (Matsuda et al.), the disclosure of which is hereby incorporated by reference.

A second solution, and one that in the long run would be more effective, is to fabricate SM thin films with as large grains as possible. With increasing grain size the grain boundary area is reduced and the stresses developed are greatly reduced.

The paper, “Driving Force and Mechanism for Spontaneous Metal Whisker Formation,” Barsoum, M. W. et al., Physical Review Letters, Vol. 93, No. 20, 12 November 2004, may contain further details regarding the invention and thus is hereby incorporated by reference for this purpose.

### ADDITIONAL REFERENCES CITED HEREIN, THE DISCLOSURES OF WHICH ARE HERBY INCORPORATED BY REFERENCE

1) W. C. Ellis, D. F. Gibbons and R. G. Treuting, in: R. H. Doremus, B. W. Roberts and D. Turnbull, Eds., Growth and Perfection in Crystals, N.Y. John Wiley, 1958, p. 102.
2) F. R. N. Nabarro and P. J. Jackson, in: R. H. Doremus, B. W. Roberts and D. Turnbull, Eds., Growth and Perfection in Crystals, John Wiley, NY, 1958, p. 12.
3) U. Lindborg, Met. Trans., 6A, 1581 (1975).
4) U. Lindborg, Acta Metall., 24, 181 (1976).
5) R. M. Fisher, L. S. Darken and K. G. Carroll, Acta Met., 2, 368 (1954).
6) K. N. Tu, Acta Metall., 21, 347 (1973).
7) C. Y. Chang and R. W. Vook, Thin Film Solids, 228, 205 (1993).
8) E. Iwamura, K. Takagi and T. Ohnishi, Thin Film Solids, 349, 191 (1999).
9) D.-K. Kim, B. Heiland, W. D. Nix, E. Artz, M. D. Deal and J. D. Plummer, Thin Film Solids, 371, 278 (2000).
10) F. C. Frank, Phil. Mag., 44, 854 (1953).
11) J. D. Eshelby, Phys. Rev. 91, 755 (1953).
12) V. K. Glazunova and K. M. Gorbunova, Crystal Growth, 10, 85 (1971).
13) W. J. Choi, T. Y. Lee, K. N. Tu, N. Tamura, R. S. Celeste, A. A. MacDowell, Y. Y. Bong and L. Nguyen, Acta Mater., 51, 6253 (2003)
14) G. T. T. Sheng, C. F. Hu, W. J. Choi, K. N. Tu, Y. Y. Bong and L. Nguyen, J. Appl. Phys., 92, 64 (2002).
15) K. N. Tu, Phys. Rev. B, 49, 2030 (1994).
16) B.-Z. Lee and D. N. Lee, Acta Mater., 46, 3701 (1998).
17) W. J. Choi, T. Y. Lee, K. N. Tu, N. Tamura, R. S. Celestre; A. A. MacDowell, Y. Y. Bong, L. Nguyen, and G. T. T. Sheng, 52^{nd} Electronic Component & Technology Conference Proceedings, San Diego, Calif., 628-633 (2002).
18) K. Zheng and K. N. Tu, Materials Science and Engineering R, 38, 55 (2002).
19) K. G. Compton, A. Mendizza and S. M. Arnold, Corrosion, 7, 327 (1951).
20) G. S. Baker and J. S. Koehlere, cited in Ref. 2.
21) M. W. Barsoum, Prog. Solid State Chem., 28, 201-281 (2000).
22) M. W. Barsoum and M. Radovic, Encyclopedia of Materials Science and Technology, Eds. Buschow, Cahn, Flemings, Kramer, Mahajan and P. Veyssiere, Elsevier Science, 2004.
23) W. Jeitschko, and H. Nowotny, Monatsh. Chem., 98, 329-337 (1967).
24) M. W. Barsoum and L. Farber, L. Science, 284, 937-939 (1999).
25) T. El-Raghy, and M. W. Barsoum, Science, 285, 1355 (1999).
26) S. M. Arnold, Tech. Proc. 43^{rd} Ann. Convention Amer. Electroplaters Soc. Bell Tell System Monograph 2635 (1956).

It is to be understood, however, that even though numerous characteristics and advantages of the present invention have been set forth in the foregoing description, together with details of the structure and function of the invention, the disclosure is illustrative only, and changes may be made in detail, especially in matters of shape, size and arrangement of parts within the principles of the invention to the full extent indicated by the broad general meaning of the terms in which the appended claims are expressed.

1. A method for the reduction or prevention of metal whisker formation comprising the step of providing a sufficient oxygen or nitrogen barrier to at least a portion of a surface of a metal which has a tendency to form metal whiskers to reduce an amount of oxygen or nitrogen that contacts the metal, to thereby reduce or prevent metal whisker formation.

2. A method as claimed in claim 1, wherein the metal is selected from the group consisting of: Sn, In, Ga Cd, Bi, Zn and Al.

3. A method as claimed in claim 1, wherein the barrier is selected from the group consisting of: paints, sealants, semi-conductive polymeric coatings, and amorphous materials.

4. A method as claimed in claim 3, wherein the barrier is selected from the group consisting of paints and sealants.

5. A method as claimed in claim 4, wherein the paint or sealant is selected from the group consisting of polyvinyl chloride resins, polyanilines, vinyl acetate polymers, copolymers of vinyl acetate with other monomers, nail polish, and water-based polymers.

6. A method as claimed in claim 5, wherein the paint or sealant is a water-based polymer having a viscosity in excess of 1000 mPa/s and a solid content of about 20 to about 40% by weight.

7. A method as claimed in claim 3, wherein the barrier is a semi-conductive polymeric coating.

8. A method as claimed in claim 3, wherein the barrier is an amorphous material.

9. A method as claimed in claim 8, wherein the amorphous material is selected from the group consisting of zirconium phosphate and chromium chromate.

10. A whisker resistant composition comprising a metal which has a tendency to form metal whiskers and a sufficient amount of an oxygen or nitrigen barrier on at least a portion of a surface of the metal which has a tendency to form metal whiskers, to reduce an amount of oxygen or nitrogen in contact with the metal.

11. A composition as claimed in claim 10, wherein the metal is selected from the group consisting of: Sn, In, Ga Cd, Bi, Zn and Al.

12. A composition as claimed in claim 10, wherein the barrier is selected from the group consisting of: paints, sealants, semi-conductive polymeric coatings, and amorphous materials.

13. A composition as claimed in claim 12, wherein the barrier is selected from the group consisting of paints and sealants.

14. A composition as claimed in claim 13, wherein the paint or sealant is selected from the group consisting of polyvinyl chloride resins, polyanilines, vinyl acetate polymers, copolymers of vinyl acetate with other monomers, nail polish, and water-based polymers.

15. A composition as claimed in claim 14, wherein the paint or sealant is a water-based polymer having a viscosity in excess of 1000 mPa/s and a solid content of about 20 to about 40% by weight.

16. A composition as claimed in claim 12, wherein the barrier is a semi-conductive polymeric coating.

17. A method as claimed in claim 12, wherein the barrier is an amorphous material.

18. A method as claimed in claim 17, wherein the amorphous material is selected from the group consisting of zirconium phosphate and chromium chromate.

19. A method for the reduction of metal whisker formation in a metal having a tendency to form metal whiskers comprising the step of fabricating or depositing the metal which has a tendency to form metal whiskers in a manner whereby a large grain size is obtained.

20. A method as claimed in claim 19, comprising the steps of providing a mixed powder of Zr, In and carbon, and pressing the mixed powder at a temperature of about 700° C. to about 1400° C., and a pressure of about 50-150 MPa to form a thin film.
